(19) United States
(12) Patent Application Publication
(10) Pub. No.: US 2022/0048811 A1
(43) Pub. Date: Feb. 17, 2022

(54) QUARTZ ETCHING METHOD AND ETCHED SUBSTRATE

(71) Applicant: ULVAC COATING CORPORATION, Chichibu-shi, (JP)

(72) Inventor: Tomoaki KOJIMA, Chichibu-shi (JP)

(21) Appl. No.: 17/309,287

(22) PCT Filed: Apr. 14, 2020
(86) PCT No.: PCT/JP2020/016379

§ 371 Date: May 14, 2021

(30) Foreign Application Priority Data
May 7, 2019 (JP) 2019-087832

(51) Int. Cl. C03C 15/00; G03F 1/80; G03F 1/60

(52) U.S. Cl. CPC C03C 15/00; G03F 1/60; G03F 1/80

(57) ABSTRACT

A quartz etching method of the invention includes forming a mask on a quartz glass substrate and carrying out etching using a hydrofluoric acid-based etchant solution. The quartz etching method includes: preparing a quartz glass substrate; forming a mask having a predetermined pattern on the quartz glass substrate; and carrying out etching on the quartz glass substrate. When the quartz glass substrate is prepared, the quartz glass substrate is selected in accordance with a standard such that a concentration of hydroxyl groups included therein is less than or equal to 300 ppm.

### CROSS REFERENCE TO RELATED APPLICATIONS

This application is a National Stage Application of PCT/JP2020/016379, filed on Apr. 14, 2020 and claims priority from Japanese Patent Application No. 2019-087832 filed on May 7, 2019, the contents of which are incorporated herein by reference in their entirety.

### FIELD

The present invention relates to a quartz etching method and an etched substrate and particularly relates to a preferred technique used when a quartz substrate or the like is processed by etching.

### BACKGROUND

In some cases, for a product using a photomask or another quartz glass substrate, quartz is partially subjected to wet etching with an etchant in order to obtain a predetermined shape.

At that time, after a predetermined part is masked, a glass substrate is immersed in a chemical solution (for example, hydrofluoric acid, ammonium fluoride, potassium hydroxide, or the like) capable of etching the substrate, and therefore only a region which is not covered with the mask and at which glass is exposed is corroded (etched).

Chromium (Cr) is used as a material of a metal mask in wet etching using a hydrofluoric acid-based etchant with respect to a glass substrate. (Patent Document 1)

Here, for the aforementioned etching, an amount of etching needs to be uniform at each position on a surface of the glass substrate which is subjected to etching treatment (Patent Documents 2 and 3).

### PRIOR ART DOCUMENTS

### Patent Documents

[Patent Document 1] PCT International Publication No. WO 2014/080935

### [Patent Document 2] Japanese Patent No. 5796598

### [Patent Document 3] Published Japanese Translation No. 2010-502538 of the PCT International Publication

### SUMMARY

### Problems to be Solved by the Invention

However, even in cases where conditions of an etchant are accurately coordinated with each other as well as conditions of etching, there are problems in that an amount of etching for each position on the surface of the glass substrate may vary or an amount of etching may vary for each glass substrate.

Particularly, regarding a profile of difference in an amount of etching at each position on the surface of the glass substrate, since such a profile is similarly obtained on the top surface and the back surface of the glass substrate, it is conceivable that a variation in the amount of etching occurs due to the material of the glass substrate.

The invention was conceived in view of the above-described circumstances and achieves the following objects.

1. Improvement of accuracy of etching quartz.

2. Reduction in occurrence of a variation in the amount of etching for each position on a surface in etching a quartz glass substrate.

3. Reduction in occurrence of a variation in the amount of etching for each substrate in etching quartz glass substrates.

4. Reduction in occurrence of a variation in the amount of etching for each batch to be processed in etching quartz glass substrates.

### Means for Solving the Problems

Here, processing with a high level of accuracy such as approximately several % with respect to a depth of etching is required for processing of MEMS packages, sensor components, optical components, or the like. In particular, in the case in which tolerance of ±several μm is necessary for deep etching processing such as approximately several hundreds of μm, the proportion of a permitted variation with respect to a depth of etching is approximately 1%.

For etching, a chemical reaction, etching processing is carried out at a constant speed (etching rate).

It is conceivable that, as a variation in etching rate, there are a variation in etching rate (a variation thereof on a surface of a substrate) at a plurality of points on a surface of each substrate (for example, at a central portion, a peripheral portion, or the like on a surface of a substrate) and a variation in etching rate for each of a plurality of substrates (a variation between substrates). The variation in etching rate is represented by the variation in the depth of etching and the width of the aforementioned two variations which are finally obtained.

That is, regarding the variation in delta depth of etching which is a variation in depth of etching, there is a relationship of “variation in delta etching rate”×“etching time”=“variation in delta depth of etching”.

Therefore, the longer the etching time, the more the variation in depth of etching increases.

In other words, there is a relationship of “variation in delta etching rate %”×“depth of etching”=“variation in delta depth of etching”.

Therefore, the deeper the depth of etching, the more the value of the variation in delta depth of etching increases.

However, generally, in the case in which a variation in processing depth (depth of etching) is approximately 10 μm or 100 μm, for example, it is possible to preset the tolerance thereof to be ±several μm in advance. In contrast, the deeper the processing depth, the higher the level of difficulty of ensuring the accuracy.

Naturally, the same applies to the case in which the processing depth is shallow and the tolerance is strict. For example, in the case in which the tolerance is 1% with respect to the processing depth, a variation in etching rate at least due to the material has to be 1% or less, and if not, it is not possible to satisfy the required processing accuracy even if factors other than the variation in the material are omitted.

The invention was conceived in view of the above-described circumstances and can maintain required accuracy such as approximately ±2.5 μm in the case of carrying out the processing to provide a depth of, for example, approximately 250 μm.

Note that, in Patent Documents 2 and 3, the processing accuracy is at the same level as that of the target of the invention, and a 1% level-variation in etching is discussed.

A quartz etching method according to an aspect of the invention includes forming a mask on a quartz glass substrate and carrying out etching using a hydrofluoric acid-based etchant solution. The quartz etching method includes preparing a quartz glass substrate (preparation step), forming a mask having a predetermined pattern on the quartz glass substrate (mask formation step), and carrying out etching on the quartz glass substrate (etching step). When the quartz glass substrate is prepared (in the preparation step), the quartz glass substrate is selected in accordance with a standard such that a concentration of hydroxyl groups included therein is less than or equal to 300 ppm. Consequently, the aforementioned problem is solved.

In the aspect of the invention, when the quartz glass substrate is prepared (in the preparation step), the quartz glass substrate may be selected in accordance with a standard such that birefringence thereof is less than or equal to 10 nm/cm.

In the aspect of the invention, when the quartz glass substrate is prepared (in the preparation step), it is preferable that the quartz glass substrate be selected in accordance with a standard such that the quartz glass substrate is formed of synthetic quartz produced by a vapor-phase axial deposition method.

In the aspect of the invention, when the quartz glass substrate is prepared (in the preparation step), the quartz glass substrate may be selected in accordance with a standard such that the quartz glass substrate is stria free.

Furthermore, in the aspect of the invention, when the mask is formed (in the mask formation step), the mask may contain at least chromium as a main component.

In the invention, when the quartz glass substrate is etched (in the etching step), the quartz glass substrate may be immersed in the hydrofluoric acid-based etchant solution.

Moreover, it is preferable that an etched substrate according to an aspect of the invention be produced by any one of the above-described quartz etching methods.

The quartz etching method according to the aspect of the invention is a quartz etching method of forming a mask on a quartz glass substrate and carrying out etching using a hydrofluoric acid-based etchant solution, and includes: the preparation step of preparing a quartz glass substrate; the mask formation step of forming a mask having a predetermined pattern on the quartz glass substrate; and the etching step of carrying out etching on the quartz glass substrate, wherein, in the preparation step, the quartz glass substrate is selected in accordance with a standard such that a concentration of hydroxyl groups included therein is less than or equal to 300 ppm. Accordingly, it is possible to prevent the occurrence of the variation in the amount of etching at the etched portions, that is, the portions at which the mask is not formed. Specifically, the variation in depth of etching after the etching step is carried out, that is, the variation in the amount of etching due to differences in positions of the etched portions on the surface of the quartz glass substrate serving as a substrate to be processed, is reduced. Furthermore, the variation in the amount of etching at the etched portions on the surface of each of various quartz glass substrates in the same batch processing is reduced. Additionally, the variation in the amount of etching due to differences in positions of the etched portions on the surfaces of the quartz glass substrates of the various batches is reduced. Moreover, not only is it possible to reduce occurrence of these variations, but the variation itself, that is, the difference in etching depth, can also be reduced.

As a typical method of manufacturing synthetic quartz glass, a direct method and a soot method are known. In both methods, SiO₂ is synthesized by combusting SiCl₄ to be a material together with H₂ and O₂.

The direct method is a method of hydrolyzing silicon tetrachloride (SiCl₄) in an oxyhydrogen flame, directly carrying out deposition and vitrification, and therefore synthesizing silica glass.

In the soot method, silica particles are firstly generated and therefore a porous solid is formed. Next, a hydroxyl group is controlled by heat treatment in a suitable atmosphere. Finally, transparent vitrification is carried out at a high temperature. Since this synthetic method includes a plurality of steps, glass aspects are easily controlled.

Here, main impurities of glass are hydroxyl groups and chloro groups which are included in the configurations of Si—OH and Si—Cl. Generally, in glass produced by a direct method, the concentration of hydroxyl groups is approximately 400 to 1500 ppm. In addition, in glass produced by a vapor-phase axial deposition method classified as a soot method, the concentration of hydroxyl groups is less than or equal to 200 ppm. There is such difference between glasses produced by the direct method and the soot method.

As a result of adopting the quartz glass substrate containing hydroxyl groups as a main impurity at a concentration of 300 ppm or less, the variation in composition which causes a variation in etching rate is reduced, and the variation in etching rate can be less than or equal to 1%.

In the quartz etching method according to the aspect of the invention, in the preparation step, the quartz glass substrate can be selected in accordance with a standard such that birefringence thereof is less than or equal to 10 nm/cm. Consequently, the concentration of the included hydroxyl groups can be less than or equal to 300 ppm. Accordingly, it is possible to prevent the occurrence of the variation in the amount of etching at the etched portions, that is, at the portions at which the mask is not formed. Specifically, the variation in depth of etching after the etching step is carried out, that is, the variation in the amount of etching due to differences in positions of the etched portions on the surface of the quartz glass substrate serving as a substrate to be processed, is reduced. Furthermore, the variation in the amount of etching at the etched portions on the surface of each of various quartz glass substrates in the same batch processing is reduced. Additionally, the variation in the amount of etching due to differences in positions of the etched portions on the surfaces of the quartz glass substrates of the various batches is reduced. Moreover, not only is it possible to reduce occurrence of these variations, but the variation itself, that is, the difference in etching depth, can also be reduced.

This is because the stress and the distortion of glass also affects the etching rate.

It is known that the remnant stress inside the glass causes birefringence. According to the invention, the variation in etching rate can be less than or equal to 1% by setting the birefringence of the quartz glass substrate to be less than or equal to 10 nm/cm.

Furthermore, the birefringence indicates not only the remaining stress that was not removed in a step of manufacturing a silica glass but also the value reflecting the entire stress remaining in the substrate such as a stress or the like which occurs when cutting the substrate in a post step. Consequently, determination of a glass substrate with reference to the birefringence is a reasonable indicator in order to reduce the variation in etching rate due to the variation in stress.

In the quartz etching method according to the aspect of the invention, in the preparation step, the quartz glass substrate is selected in accordance with a standard such that the quartz glass substrate is formed of synthetic quartz produced by a vapor-phase axial deposition method. Because of this, the concentration of the included hydroxyl groups can be less than or equal to 300 ppm and the birefringence can be less than or equal to 10 nm/cm. Accordingly, it is possible to prevent the occurrence of the variation in the amount of etching at the etched portions, that is, at the portions at which the mask is not formed. Specifically, the variation in depth of etching after the etching step is carried out, that is, the variation in the amount of etching due to differences in positions of the etched portions on the surface of the quartz glass substrate serving as a substrate to be processed, is reduced. Furthermore, the variation in the amount of etching at the etched portions on the surface of each of various quartz glass substrates in the same batch processing is reduced. Additionally, the variation in the amount of etching due to differences in positions of the etched portions on the surfaces of the quartz glass substrates of the various batches is reduced. Moreover, not only is it possible to reduce occurrence of these variations, but the variation itself, that is, the difference in etching depth, can also be reduced.

This is because the quartz glass substrate produced by the soot method (vapor-phase axial deposition method) has a characteristic that, since the temperature thereof in synthesis is low, an amount of doping of impurities such as chlorine, metal, or the like thereinto is low.

The soot method includes steps of firstly generating silica particles and thereby forming a porous solid and subsequently carrying out sintering transparent vitrification by heat treatment in a suitable atmosphere (vacuum, He, or the like). Consequently, in the sintering transparent vitrification step of the soot method, an OH concentration and a chlorine concentration can be controlled in predetermined ranges.

Therefore, the OH concentration is in the range of 1 ppm to 200 ppm, metal is in the range of less than 0.01 ppm, and chlorine is in the range of 300 ppm or less. Furthermore, chlorine can be substantially completely omitted such as less than or equal to 1 ppm. Accordingly, it is possible to reduce impurities which affect the etching rate. As a result, it is preferable to select the quartz glass substrate that is produced by a vapor-phase axial deposition method.

In the quartz etching method according to the aspect of the invention, in the preparation step, the quartz glass substrate is selected in accordance with a standard such that the quartz glass substrate is stria free. Accordingly, it is possible to prevent the occurrence of the variation in the amount of etching at the etched portions, that is, at the portions at which the mask is not formed. Specifically, the variation in depth of etching after the etching step is carried out, that is, the variation in the amount of etching due to differences in positions of the etched portions on the surface of the quartz glass substrate serving as a substrate to be processed, is reduced. Furthermore, the variation in the amount of etching at the etched portions on the surface of each of various quartz glass substrates in the same batch processing is reduced. Additionally, the variation in the amount of etching due to differences in positions of the etched portions on the surfaces of the quartz glass substrates of the various batches is reduced. Moreover, not only is it possible to reduce occurrence of these variations, but the variation itself, that is, the difference in etching depth, can also be reduced.

Here, in the direct method, since vitrification is carried out at the same time as synthesis of SiO₂, a variation in composition occurs due to a change (pulsation) in the flow rate of a material gas (SiCl₄, H₂, O₂), and striae (layers) are easily generated.

In contrast, the soot method includes a manufacturing process of at least two or more steps which are: a step of firstly generating silica particles and thereby forming a porous solid; and a step of subsequently carrying out sintering transparent vitrification by heat treatment in a suitable atmosphere (vacuum, He, or the like). Therefore, in the soot method, not only adjustment of the concentration of hydroxyl groups or the concentration of chloro groups but also control of aspects such that elimination of striae or the like is achieved are easy. Accordingly, it is preferable to select the stria-free quartz glass substrate that is produced by a vapor-phase axial deposition method.

Note that each of the striae is a different portion in a chemical component in the glass and is observed as a line form or a layer form. For example, a stria inspection device including a point light source and a lens is used, inspection is carried out at a position at which the striae inside the glass having a polished opposed surface are extremely clearly observed while comparing with the standard sample designated by Japan Optical Glass Manufacturers' Association, and the case in which the striae cannot be observed is referred to as stria free.

Moreover, in the quartz etching method according to the aspect of the invention, in the mask formation step, the mask contains at least chromium as a main component. Because of this, the portions other than the etched portions can be protected from the etchant.

In the quartz etching method according to the aspect of the invention, in the etching step, the quartz glass substrate is immersed in the hydrofluoric acid-based etchant solution. As a result, a plurality of quartz glass substrates is processed in a batch at the same time, and processing of a plurality of batches can be carried out by performing this processing two or more times.

Furthermore, the etched substrate according to the aspect of the invention can be produced by any one of the above-described quartz etching methods.

### Effects of the Invention

According to the aspect of the invention, regarding the variation in the amount of etching at the etched portions, it is possible to obtain an effect of reducing the variation due to the positions of the etched portions on the surface of the substrate, due to differences of the quartz glass substrates in the same batch processing, and due to differences in batch processing.

### BRIEF DESCRIPTION OF THE DRAWINGS

FIG. 1 is a cross-sectional process view showing a quartz etching method according to a first embodiment of the invention.

FIG. 2 is a cross-sectional process view showing the quartz etching method according to the first embodiment of the invention.

FIG. 3 is a cross-sectional process view showing the quartz etching method according to the first embodiment of the invention.

FIG. 4 is a cross-sectional process view showing the quartz etching method according to the first embodiment of the invention.

FIG. 5 is a cross-sectional process view showing the quartz etching method according to the first embodiment of the invention.

FIG. 6 is a cross-sectional process view showing the quartz etching method according to the first embodiment of the invention.

FIG. 7 is a flowchart showing the quartz etching method according to the first embodiment of the invention.

FIG. 8 is a view showing an experimental example of the quartz etching method according to an example of the invention and is a schematic view showing etching positions on an etched quartz substrate.

FIG. 9 is a view showing an experimental example of the quartz etching method according to an example of the invention and is a graph showing a variation in the amount of etching.

FIG. 10 is a view showing an experimental example of the quartz etching method according to an example of the invention and is a graph showing a variation in the amount of etching.

FIG. 11 is a view showing an experimental example of the quartz etching method according to an example of the invention and is a graph showing a variation in the amount of etching.

FIG. 12 is a view showing an experimental example of the quartz etching method according to an example of the invention and is a graph showing a variation in the amount of etching.

FIG. 13 is a view showing an experimental example of the quartz etching method according to an example of the invention and is a view showing a distribution of an amount of etching.

FIG. 14 is a view showing an experimental example of the quartz etching method according to an example of the invention and is a view showing a distribution of an amount of etching.

FIG. 15 is a view showing an experimental example of the quartz etching method according to an example of the invention and is a view showing a distribution of an amount of etching.

FIG. 16 is a view showing an experimental example of the quartz etching method according to an example of the invention and is a view showing a distribution of an amount of etching.

FIG. 17 is a view showing an experimental example of the quartz etching method according to an example of the invention and is a view showing a distribution of an amount of etching.

FIG. 18 is a view showing an experimental example of the quartz etching method according to an example of the invention and is a graph showing a variation in the amount of etching.

FIG. 19 is a view showing an experimental example of the quartz etching method according to an example of the invention and is a view showing a distribution of an amount of etching.

FIG. 20 is a view showing an experimental example of the quartz etching method according to an example of the invention and is a view showing a distribution of an amount of etching.

FIG. 21 is a view showing an experimental example of the quartz etching method according to an example of the invention and is a graph showing a variation in the amount of etching.

### DETAILED DESCRIPTION

Hereinafter, a quartz etching method and an etched substrate according to a first embodiment of the invention will be described with reference to the drawings.

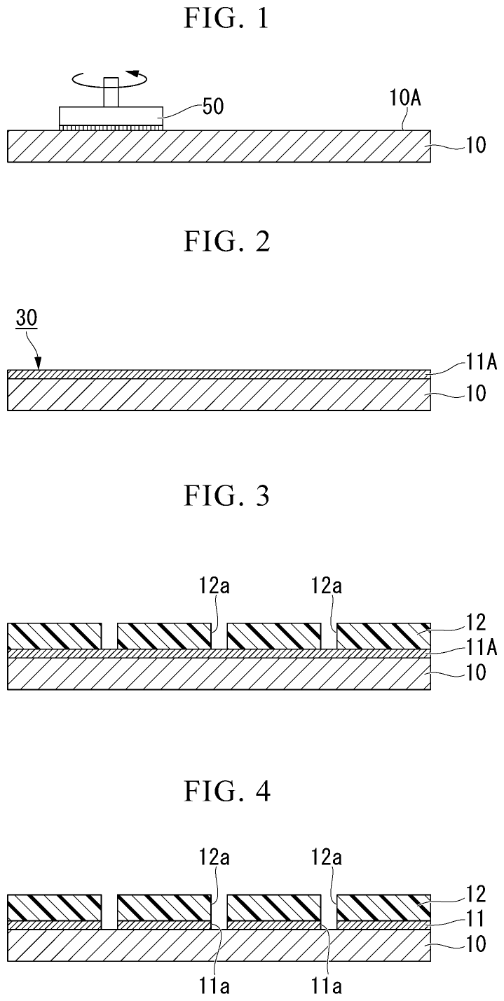

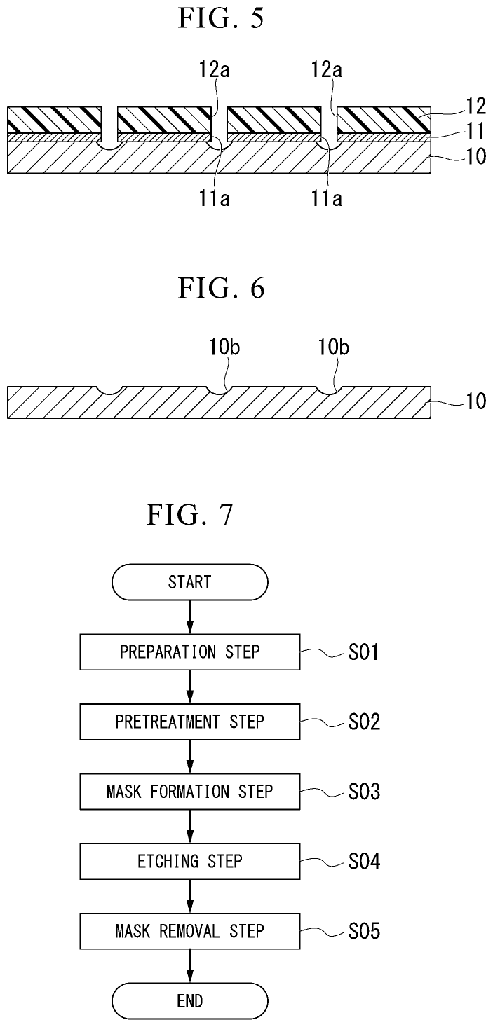

FIGS. 1 to 6 are cross-sectional process views showing the etching method according to the embodiment, FIG. 7 is a flowchart showing the quartz etching method according to the embodiment, and reference numeral 10 represents a quartz glass substrate in the drawings.

The quartz etching method according to the embodiment is an etching method of forming a mask 11 on the quartz glass substrate 10 and carrying out etching using a hydrofluoric acid-based etchant solution (etchant).

As shown in FIGS. 1 to 7, the quartz etching method according to the embodiment includes a preparation step S01, a pretreatment step S02, a mask formation step S03, an etching step S04 of carrying out etching on the quartz glass substrate, and a mask removal step S05.

In the preparation step S01 shown in FIG. 7, the quartz glass substrate 10 that satisfies predetermined standards is prepared.

Specifically, the quartz glass substrate 10 is selected in accordance with the standard such that the concentration of hydroxyl groups included therein is less than or equal to 300 ppm, preferably, less than or equal to 200 ppm and greater than or equal to 0 ppm.

At this time, the quartz glass substrate 10 is selected in accordance with the standard such that the birefringence thereof is less than or equal to 10 nm/cm and greater than or equal to 1 nm/cm. Furthermore, the quartz glass substrate 10 is selected in accordance with the standard such that the quartz glass substrate is formed of synthetic quartz produced by a vapor-phase axial deposition method. In addition, the quartz glass substrate 10 is selected in accordance with the standard such that the quartz glass substrate is stria free.

In the pretreatment step S02 of the quartz etching method according to the embodiment, as shown in FIG. 1, a processing surface 10A of the quartz glass substrate 10 to be subjected to etching is polished and the polished quartz glass substrate 10 is cleaned.

Here, the processing surface 10A of the quartz glass substrate 10 is polished using, for example, a polishing pad 50 and polishing liquid containing cerium oxide, preferably colloidal silica, as a main component. The number of polishing steps may be 0 times to multiple times which are freely selected. The quartz glass substrate 10 that was subjected to the polishing treatment is cleaned by a known cleaning method and thus the polishing liquid or the like adhered to the surface of the substrate is removed. Generally, as a method of cleaning of the quartz glass substrate 10, cleaning is carried out using a detergent, and then cleaning using deionized-water is carried out.

After the pretreatment step S02 is completed, the mask 11 having a predetermined pattern is formed on the quartz glass substrate 10 in the mask formation step S03 shown in FIG. 7.

Here, there are a mask material film formation step and an etching mask formation step. In the mask material film formation step, a mask material film (mask) 11A that serves as an etching mask 11 is formed on the quartz glass substrate 10. In the etching mask formation step, a resist pattern 12 is formed on the mask material film 11A by patterning, the mask material film 11A is partially removed through the resist pattern 12 serving as a mask, and the etching mask 11 is thereby obtained.

In the mask material film formation step, as shown in FIG. 2, a mask material film (mask) 11A serving as the etching mask 11 is formed on the quartz glass substrate 10. As described above, the quartz glass substrate 10 and the mask material film 11A constitute a layered structure 30. The mask material film 11A includes a main layer having a film that is formed of chromium as a main component and contains nitrogen at greater than or equal to 15 atom % and less than 39 atom %. Alternatively, as the mask material film 11A, a laminated metal chromium/gold (Cr/Au) or the like may be used. Note that an average thickness of a chromium film serving as the mask material film 11A may be 5 to 500 nm, for example, 100 to 300 nm.

As a method of forming the chromium film serving as the mask material film 11A, it is preferable to use a sputtering method in consideration of mass productivity or the like. In this case, as a sputtering gas, it is preferable to use a mixed gas of argon gas, nitrogen gas, and carbon dioxide gas, and a flow ratio can be set so as to obtain a desired stress and reflectance. Particularly, a condition such as the flow rate of the nitrogen gas or the like is set such that the concentration of nitrogen included in the film is in the aforementioned range. Note that, as a sputtering apparatus, an apparatus including a known configuration can be used.

Here, film formation may be carried out such that the film composition of the mask material film 11A is adjusted to include nitrogen at greater than or equal to 15 atom % and less than 39 atom %. In the case of causing the mask material film 11A to contain nitrogen for adjusting the resistance of the mask material film 11A with respect to the etchant, it is preferable to form a film by a reactive sputtering method. In this case, when the mask material film 11A is formed, it is only necessary to add nitrogen into an inert gas such as argon or the like serving as a sputtering gas while using a target having a predetermined composition (chromium). Furthermore, oxygen such as various nitrogen oxides, various carbon oxides, or the like, nitrogen, a gas including carbon or the like may be adequately added. In addition, the concentration of nitrogen of the mask material film 11A is controlled by the proportion of the sputtering gas and sputtering power.

In the etching mask formation step, the resist pattern 12 is formed on the mask material film 11A by patterning, the mask material film 11A is partially removed through the resist pattern 12 serving as a mask, and the etching mask 11 is thereby obtained.

Here, firstly, resist is applied onto the mask material film 11A of the layered structure 30, the resist is subjected to treatment of exposure and development, and therefore the resist pattern 12 having openings 12a is formed as shown in FIG. 3. Alternatively, a dry film may be used.

Next, as shown in FIG. 4, the mask material film 11A is partially removed by wet etching treatment using the resist pattern 12 as a mask, and therefore openings 11a communicated with the openings 12a of the resist pattern 12 are formed on the mask material film 11A. Consequently, the etching mask 11 having a plane pattern having a predetermined shape is obtained.

In the etching step S04 shown in FIG. 7, the etching mask 11 and the resist pattern 12 which are formed on the quartz glass substrate 10 are used as masks, and wet etching treatment using a hydrofluoric acid-based etchant solution is carried out.

As an etching solution, for example, an etching solution including hydrofluoric acid (a hydrofluoric acid-based etching solution) can be used. The etching solution including hydrofluoric acid is not particularly limited. In the case in which the target processing speed is fast, the concentration of hydrofluoric acid can be set high. In the case in which the processing speed is slow, the concentration of hydrofluoric acid can be set low.

Etching of the quartz glass substrate 10 proceeds isotropically through the openings 11a of the etching mask 11 which are continuously connected to the openings 12a of the resist pattern 12. For this reason, as shown in FIG. 5, a recessed portion 10b having a semicircular shape in a cross section is formed at the positions corresponding to the openings 11a. A hydrofluoric acid-based etchant is generally used in the etching treatment of the quartz glass substrate 10. As the hydrofluoric acid-based etchant, hydrofluoric acid, a compound solution of hydrofluoric acid and an inorganic acid, or BFH containing ammonium fluoride added to hydrofluoric acid can be used.

Specifically, in the wet etching treatment, the following etching apparatus is used.

The etching apparatus includes a substrate support unit, a reservoir, a swing unit, and a circulation unit.

In the etching apparatus, a plurality of the quartz glass substrates 10 are supported by the substrate support unit such that the plurality of quartz glass substrates 10 form one batch. Furthermore, the plurality of quartz glass substrates 10 and the substrate support unit are immersed in the etching solution stored in the reservoir.

At the same time, the swing unit supports the substrate support unit and can swing the substrate support unit. Moreover, the circulation unit can circulate the etching solution inside the reservoir in a state in which the quartz glass substrates 10 are immersed in the etching solution of the reservoir.

Accordingly, the etching apparatus carries out wet etching treatment such that, for example, five quartz glass substrates 10 form one batch.

After immersion in the etching solution is carried out for a predetermined amount of time, the plurality of quartz glass substrates and the substrate support unit are pulled up from the reservoir, and the etching solution is rinsed off the quartz glass substrates 10 by a rinsing unit.

As stated above, the amounts of etching at the etched portions corresponding to the plurality of openings 11a for each of the plurality of quartz glass substrates 10 are made uniform by swinging the quartz glass substrates 10 and circulating the etching solution.

Furthermore, new quartz glass substrates 10 are set to the substrate support unit in place of the processing-completed quartz glass substrates 10, and subsequent batch processing is carried out.

In the mask removal step S05, as shown in FIG. 6, the etching mask 11 and the resist pattern 12 which are on the quartz glass substrate 10 are peeled off using a known peeling method, and it is possible to obtain the quartz glass substrate having the recessed portions 10b which constitute a microscopic uneven structure and are formed on one surface thereof. The quartz glass substrate can be used as a photomask, MEMS (Micro Electro Mechanical Systems), a specific functional part such as a biochip typified by a DNA (deoxyribonucleic acid) chip and utilized in the field of biotechnology, a production intermediate thereof, or the like.

In the embodiment, the recessed portions 10b are formed on the quartz glass substrate 10 by wet etching.

At this time, by preparing the quartz glass substrates 10 in accordance with the predetermined standard in the preparation step S01 as described above, the amounts of etching at the recessed portions 10b which are the etched portions can be equal to each other for one quartz glass substrate 10. Furthermore, the amounts of etching at the recessed portions 10b which are the etched portions can be equal to each other for the plurality of quartz glass substrates 10 of the same batch. Additionally, the amounts of etching at the recessed portions 10b which are the etched portions can be equal to each other for the plurality of quartz glass substrates 10 of each of various batches.

In the embodiment, it is necessary to note the following points.

At least in the case in which the etching rates are not uniform at the positions different from each other on one surface the quartz glass substrate 10, processing cannot be carried out such that all chips which are aligned on the quartz glass substrate 10 have the same shape.

For this reason, on one surface the quartz glass substrate 10, the etching rates at the positions different from each other need to be uniform.

Additionally, in the case of processing large quartz glass substrates having sizes of approximately six square inches which is described in the examples, the etching rate distribution of the quartz glass substrate needs to be uniform regardless of the positions of the quartz glass substrate.

For this reason, on one surface the quartz glass substrate 10, the etching rates at the positions different from each other need to be uniform.

Here, single wafer processing in which substrates are processed one by one while controlling each of the depths of the plurality of etched portions for each quartz glass substrate is known. According to the processing method, as long as the etching rate distribution is uniform on a surface of the quartz glass substrate, sufficient processing accuracy at each of the processing positions can be maintained. However, in this case, the productivity is inferior.

In contrast, the batch processing in which a plurality of quartz glass substrates is processed at the same time is advantageous in productivity as compared with the single wafer processing. However, in order to achieve the processing of a plurality of quartz glass substrates in the batch processing at the same time, it is necessary for the etching rates to be uniform at all of the etched portions of each of the quartz glass substrates to be processed at least in the same batch.

Consequently, the etching rates at all positions of the plurality of quartz glass substrates 10 to be processed in the same batch need to be uniform.

Furthermore, when the quartz glass substrates forming a batch, that is, the plurality of quartz glass substrates to be processed in the same batch, are selected, in the case in which substrates having etching rates different from each other are mixed, it is not possible to classify the substrates for each etching rate. For this reason, in the case in which substrates having etching rates different from each other are mixed, it is not possible to form a batch, that is, it is not possible to carry out batch processing.

Because of this, regarding the quartz glass substrates 10 to be processed in the same batch, it is necessary for the etching rates of all substrates to be the same as each other.

Furthermore, in the case in which etching rates are different from each other depending on a lot of the quartz glass substrates, it is necessary to classify the batch for each lot. In this case, it is difficult to classify the batch depending on the fractional number. Moreover, in this case, the time and effort for measuring an etching rate for each lot in advance increases.

Accordingly, regarding the quartz glass substrates 10 to be processed in the same batch, it is necessary for the etching rates of all lots to be the same as each other.

Note that the shape of the recessed portion 10b can be adequately selected.

### EXAMPLES

Hereinafter, experimental examples of the quartz etching method according to examples of the invention will be described.

### Experimental Examples 1 to 3

As a quartz glass substrate, a quartz glass substrate (vapor-phase axial deposition method, hydroxyl groups: 200 ppm or less, birefringence: 10 nm/cm or less) having a thickness of 1 mm and sizes of six square inches were used. Firstly, the quartz glass substrate was cleaned using detergent and deionized water, and thereafter a chromium film was formed under the following conditions using a DC sputtering method.

Sputtering gas: Ar/N₂=86/8 (sccm)

DC power: 1.6 kW

As a result of AES analyzing at the film thickness of 150.0 nm of the formed chromium film, a gaseous component contained in the formed chromium film was 0/C/N=10/6/15 atom %.

Positive photosensitive resist was applied onto the formed chromium film by a spin coater to a film thickness of 1 μm. Next, the photosensitive resist was exposed and subjected to a development process, the chromium film was etched using a chromium etching solution containing Diammonium cerium nitrate as a main component, and thereafter an etching mask pattern on the quartz glass substrate was obtained.

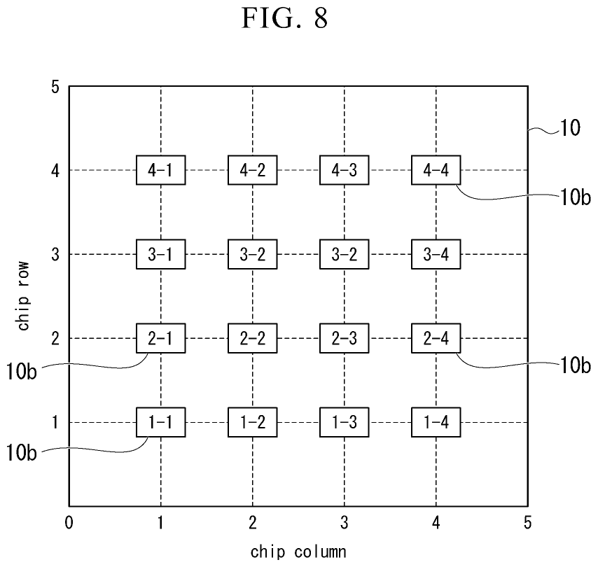

Here, the etched portions of one quartz glass substrate were set at four points for each of the vertical and horizontal directions, that is, sixteen points as shown in FIG. 8. In FIG. 8, the etched portions are represented by reference numerals 1-1, 1-2, to, 4-4.

Note that the distance in vertical and horizontal directions between the etched portions was set to 40 mm. In addition, regarding the etched portions, the surface area of one point was set to 5 mm×5 mm.

Next, five quartz glass substrates per batch were set, and etching of the quartz glass substrates was carried out by the etching apparatus by immersing the quartz glass substrates in a glass etching solution containing hydrofluoric acid as a main component while swinging the quartz glass substrates and circulating the etching solution.

Additionally, the conditions of the etching treatment were set as follows.

Etchant solution; BHF

Therefore, the etching was carried out such that the depths of etching at the etched portions were 250 μm.

Furthermore, three batches were repeated, and the batches were each of experimental examples 1 to 3.

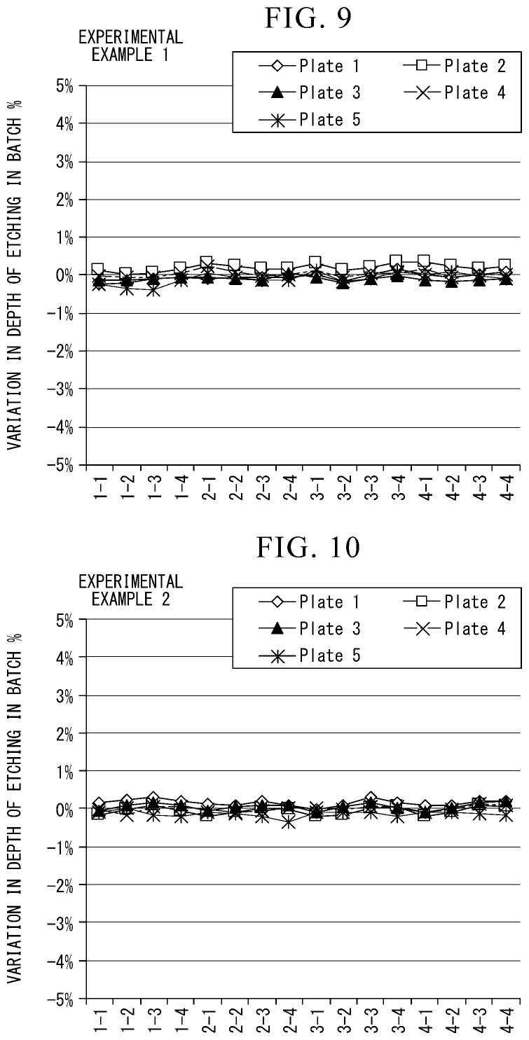

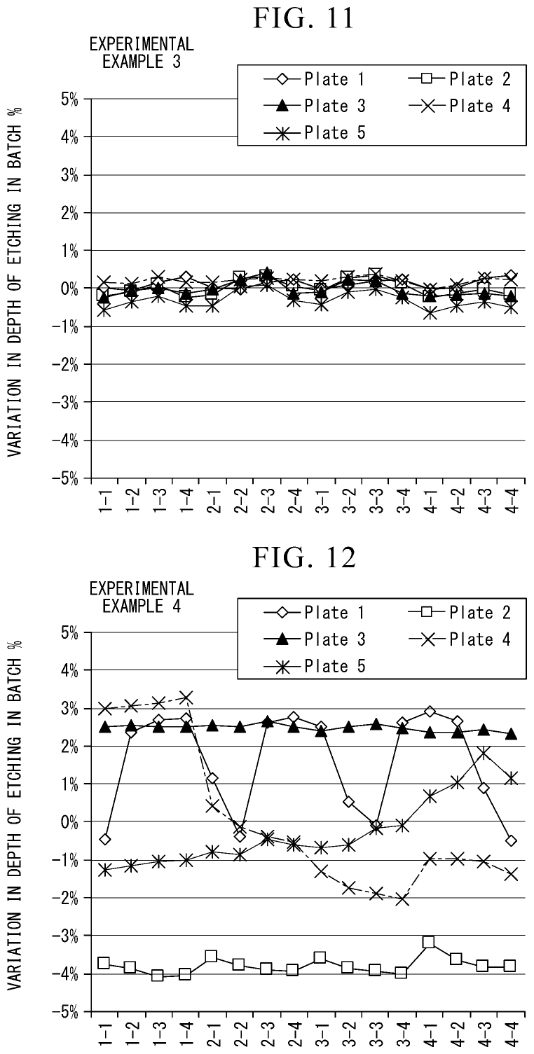

For the batch of each experimental example, the amounts of etching at the etched portions of each quartz glass substrate, that is, the depths of etching were measured. The results are shown in FIGS. 9 to 11.

FIGS. 9 to 11 show the ratios % with respect to the standard based on the average value of the entire batch. Furthermore, FIGS. 9 to 11 list Plates 1 to 5 which refer to the quartz glass substrate number of each batch.

### Experimental Example 4

As a quartz glass substrate, a quartz glass substrate (direct method, hydroxyl groups: 600 to 1300 ppm, birefringence: 30 nm/cm) having a thickness of 1 mm and a size of six square inches was used. In a similar manner to the above, the etching was carried out such that the depths of etching at the etched portions were 250 μm. This was experimental example 4.

Furthermore, the amounts of etching at the etched portions of the quartz glass substrate, that is, the depths of etching were measured. The results are shown in FIG. 12.

FIG. 12 also shows the ratios % with respect to the standard based on the average value of the entire batch. Moreover, FIG. 12 lists Plates 1 to 5 which refer to the quartz glass substrate number of the batch.

Additionally, variations 3σ% and 3σ μm in depth were calculated with respect to the depths of etching of the aforementioned experimental examples 1 to 4. The results are shown in Table 1.

TABLE 1

| VARIATION | EXPERIMENTAL | EXPERIMENTAL | EXPERIMENTAL | EXPERIMENTAL |
|---|---|---|---|---|
| INSIDE BATCH | EXAMPLE 4 | EXAMPLE 1 | EXAMPLE 2 | EXAMPLE 3 |
| 3 σ % | 7.3% | 0.45% | 0.40% | 0.73% |
| 3 σ μm | 18.1 μm | 1.4 μm | 1.2 μm | 1.9 μm |
| (CONVERSION OF | | | | |
| 250 μm ETCHING) | | | | |

As shown by the above results, the quartz glass substrates (direct method, hydroxyl groups: 600 to 1300 ppm, birefringence: 30 nm/cm) of experimental example 4 had the variations of 3σ=4% in depth on the surface of the substrate and 3σ=7% between the substrates. In contrast, in the quartz glass substrates (vapor-phase axial deposition method, hydroxyl groups: 200 ppm or less, birefringence: 10 nm/cm or less) of experimental examples 1 to 3, the variation in depth could be 3σ=1% or less in both the variation on the surface of the substrate and the variation between the substrates.

### Experimental Examples 5 to 8

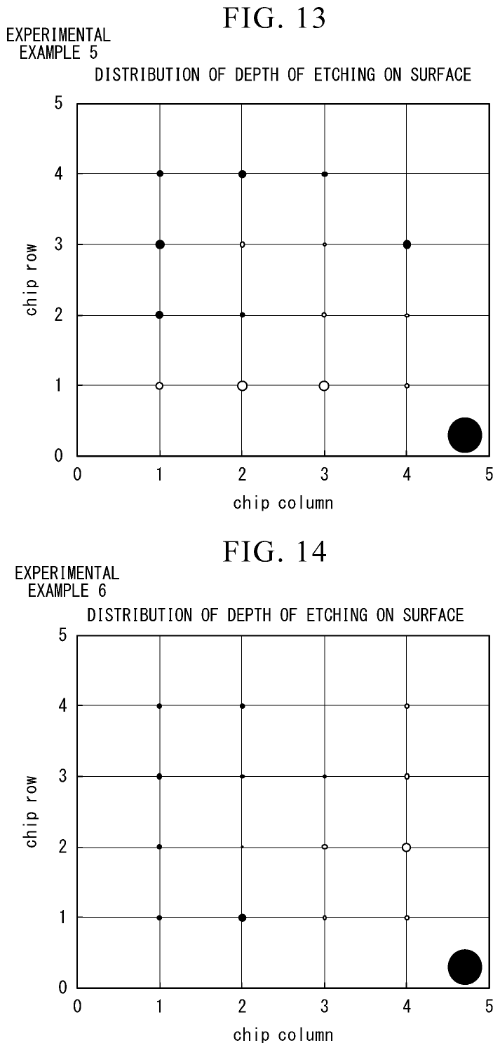

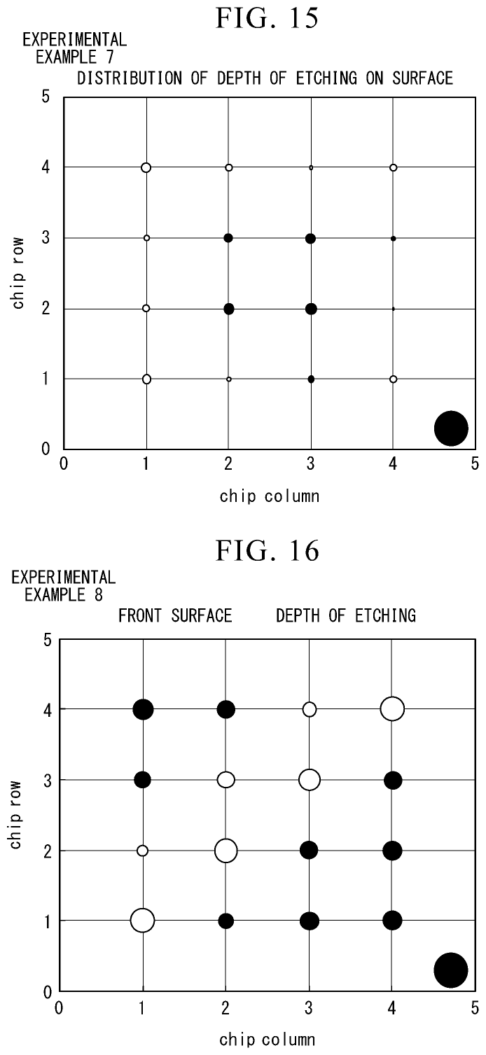

Next, for experimental examples 5 to 7, distribution of depth of etching on the surface of the fifth substrate of each batch of experimental examples 1 to 3 was measured. The results are shown in FIGS. 13 to 15.

Furthermore, for experimental example 8, distribution of depth of etching on the surface of the fifth substrate of the batch of experimental example 4 was measured. The results are shown in FIG. 16.

In FIGS. 13 to 16, the ratios % with respect to the standard based on the average value of the substrate are represented by the size of the circle (symbol “●” or symbol “◯”), the black circle (symbol “●”) indicates positive, the empty circle (symbol “◯”) indicates negative. Additionally, in FIGS. 13 to 16, the size of the circle symbol “●” that does not indicate an etched portion but indicates the rate of 4% for reference is shown at the lower right.

From the above results, it is understood that the variations on the surface of the substrate in the cases of the quartz glass substrates (vapor-phase axial deposition method, hydroxyl groups: 200 ppm or less, birefringence: 10 nm/cm or less) of experimental examples 1 to 3 are smaller than in the case of the quartz glass substrates (direct method, hydroxyl groups: 600 to 1300 ppm, birefringence: 30 nm/cm) of experimental example 8.

Furthermore, with respect to the depths of etching of the aforementioned experimental examples 1 to 4, the variations 3σ% and 3σ μm in depth of experimental examples 5 to 8 were calculated. The results are shown in Table 2.

TABLE 2

| VARIATION | EXPERIMENTAL | EXPERIMENTAL | EXPERIMENTAL | EXPERIMENTAL |
|---|---|---|---|---|
| INSIDE BATCH | EXAMPLE 4 | EXAMPLE 1 | EXAMPLE 2 | EXAMPLE 3 |
| 3 σ % | 4.0% | 0.60% | 0.36% | 0.70% |
| 3 σ μm | 9.9 μm | 1.5 μm | 0.9 μm | 1.7 μm |
| (CONVERSION OF | | | | |
| 250 μm ETCHING) | | | | |

As shown by the above results, the quartz glass substrates (direct method, hydroxyl groups: 600 to 1300 ppm, birefringence: 30 nm/cm) of experimental example 8 had the variations of 3σ=4.0% in depth on the surface of the substrate. In contrast, regarding the quartz glass substrates (vapor-phase axial deposition method, hydroxyl groups: 200 ppm or less, birefringence: 10 nm/cm or less) of experimental examples 5 to 7, the variation in depth could be 3σ=0.7% or less on the surface of the substrate.

### Experimental Examples 8 to 11

Furthermore, regarding the first and forth quartz glass substrates of the batch of the above-described experimental example 4, the distributions of depth of etching at the etched portions not only on the top surface side but also on the back surface side were measured in a manner similar to that described above, and these were experimental examples 9 to 11.

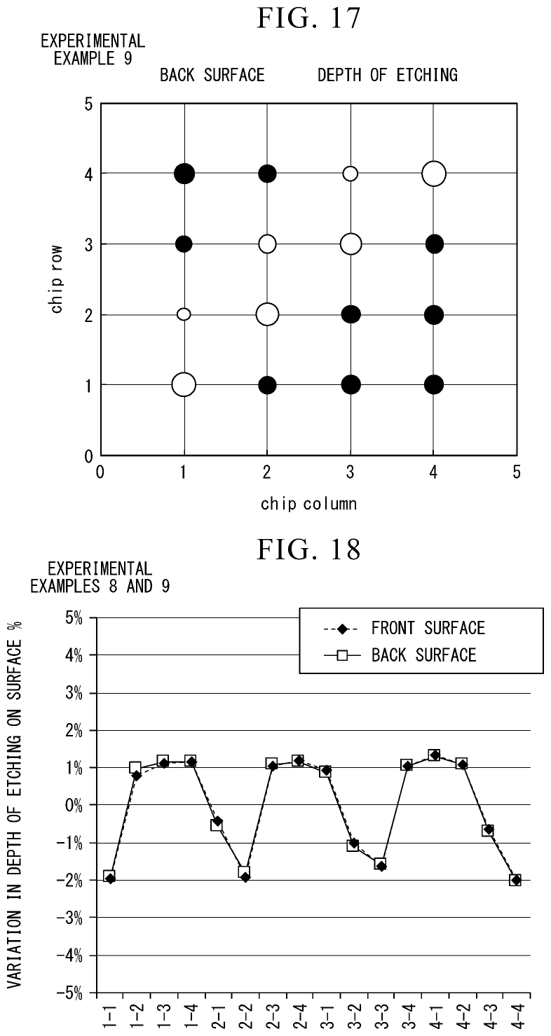

FIG. 16 shows the top surface side of the first in the batch of experimental example 4 which shows the results of experimental example 8, and FIG. 17 shows the back surface side of the first in the same batch which shows the results of experimental example 9. Additionally, FIG. 18 shows the ratios % with respect to the standard based on the average value on the top surface and the back surface of the surface of the substrate.

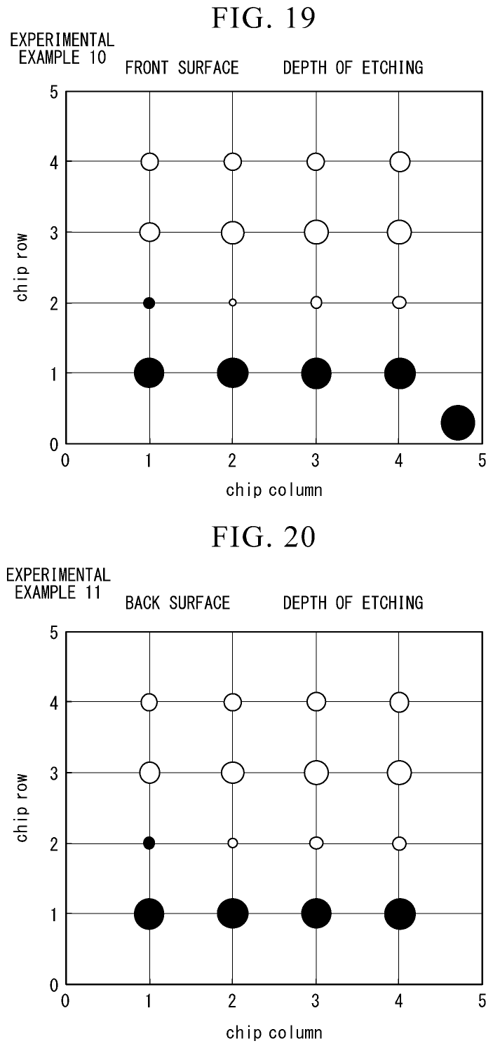

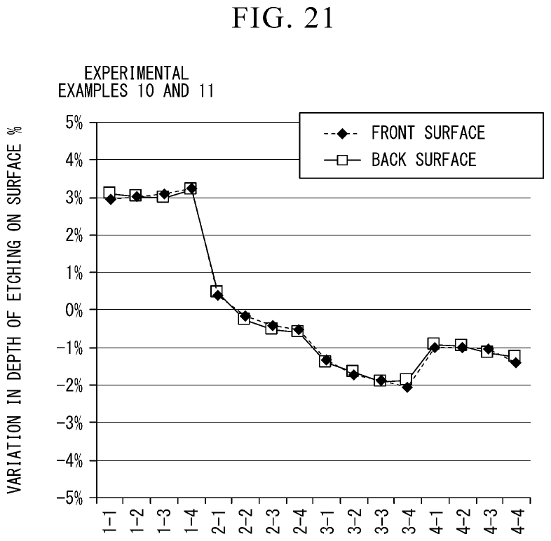

FIG. 19 shows the top surface side of the fourth in the batch of experimental example 4 which shows the results of experimental example 10, and FIG. 20 shows the back surface side of the fourth in the same batch which shows the results of experimental example 11. Moreover, FIG. 21 shows the ratios % with respect to the standard based on the average value on the top surface and the back surface of the surface of the substrate of experimental examples 8 to 11.

Note that the horizontal axis shown in FIG. 17 is arranged as a mirror image of that in FIG. 16. Similarly, the horizontal axis shown in FIG. 20 is arranged as a mirror image of that in FIG. 19.

Here, it is thought that, if the conditions of etching (etching apparatus) cause the variation in etching, the tendency of the variation in depth of etching varies on the top and the back of the quartz glass substrate, and there is no correlation therebetween.

However, as shown by the results in FIGS. 16 to 21, there is the same distribution of variation on the top and the back of the quartz glass substrate. That is, the drawing shows a bilaterally symmetric distribution. Accordingly, it is possible to consider that non-uniformity of the material causes the variation in etching.

Furthermore, the thickness of the quartz glass substrate of experimental example 4 is as thin as 1 mm, and it is thought that there is the same tendency regarding non-uniformity of the material on the top and the back of the quartz glass substrate.

Consequently, from the comparison of experimental examples 9 and 10, it is possible to consider that the variation in etching is caused by quartz (material).

### INDUSTRIAL APPLICABILITY

Particularly, as the applicable examples of the invention, cases in which deep etching processing of approximately several hundreds of μm is necessary such as a component for MEMS, a component for a sensor, or the like are adopted. Moreover, as the applicable examples of the invention, processing of quartz glass substrates in which, even where tolerance is approximately ±several μm, the proportion % of the permitted tolerance with respect to the processing depth is small, and a strict value with respect to accuracy is demanded can be adopted.

The reason for this is that, for chemical reaction processing in which the processing of the entire processing area proceeds in a constant time such as etching, as compared with the case in which, for example, the required processing accuracy is approximately 10 μm±1 μm, a degree of accuracy is strict by one-digit in the case in which the required processing accuracy is approximately 100 μm±1 μm.

For machining processing, regarding the relationship of such dimensions, since both the cases are within the tolerance of ±1 μm, it is often regarded that there is no difference in the accuracy that is substantially required. In contrast, the case of etching treatment is different from the above-described situation.

Furthermore, the invention is also effective for the intended use because a required accuracy is small (strict) even in the case in which a required processing depth is shallow such as nanoimprint, or the like.

### DESCRIPTION OF REFERENCE NUMERALS

10 . . . quartz glass substrate
10a . . . recessed portion
11 . . . mask

What is claimed is:

1. A quartz etching method of forming a mask on a quartz glass substrate and carrying out etching using a hydrofluoric acid-based etchant solution, comprising:
preparing a quartz glass substrate;
forming a mask having a predetermined pattern on the quartz glass substrate; and
carrying out etching on the quartz glass substrate, wherein
when the quartz glass substrate is prepared, the quartz glass substrate is selected in accordance with a standard such that a concentration of hydroxyl groups included therein is less than or equal to 300 ppm.

2. The quartz etching method according to claim 1, wherein
when the quartz glass substrate is prepared, the quartz glass substrate is selected in accordance with a standard such that birefringence thereof is less than or equal to 10 nm/cm.

3. The quartz etching method according to claim 1, wherein
when the quartz glass substrate is prepared,
the quartz glass substrate is selected in accordance with a standard such that the quartz glass substrate is formed of synthetic quartz produced by a vapor-phase axial deposition method.

4. The quartz etching method according to claim 1, wherein
when the quartz glass substrate is prepared, the quartz glass substrate is selected in accordance with a standard such that the quartz glass substrate is stria free.

5. The quartz etching method according to claim 1, wherein
when the mask is formed, the mask contains at least chromium as a main component.

6. The quartz etching method according to claim 1, wherein
when the quartz glass substrate is etched, the quartz glass substrate is immersed in the hydrofluoric acid-based etchant solution.

7. An etched substrate produced by the quartz etching method according to claim 1.
